(19) United States
(12) Patent Application Publication
(10) Pub. No.: US 2015/0130495 A1
(43) Pub. Date: May 14, 2015

(54) Assembly For Testing Semiconductor Devices

(71) Applicant: Texas Instruments Incorporated, Dallas, TX (US)

(72) Inventors: Dale Lee Anderson, Los Gatos (US); Artur Darbinyan, Santa Clara (US)

(21) Appl. No.: 14/527,938

(22) Filed: Oct. 30, 2014

Related U.S. Application Data
(60) Provisional application No. 61/903,672, filed on Nov. 13, 2013.

(51) Int. Cl. G01R 1/04; G01R 31/28; G01R 31/26

(52) U.S. Cl. CPC G01R 1/0441; G01R 31/2601; G01R 31/2879; G01R 31/2834
USPC 324/756.02

(57) ABSTRACT

A testing assembly for testing a plurality of semiconductor devices comprising a carrier assembly adapted to hold the plurality of semiconductor devices at predetermined locations therein that is operably connectable with a plurality of different socket assemblies. A universal socket assembly is also described.

This application claims priority of U.S. Provisional Application 61/903,672 filed Nov. 13, 2013, and of U.S. Provisional Application 61/903,681, which are both hereby incorporated by reference for all that is disclosed therein. U.S. Non-provisional Patent Application for METHOD FOR TESTING SEMICONDUCTOR DEVICES, of Anderson, et al., Ser. No. ______ (Attorney Docket No. TI-74529), filed on the same date as the present application, is hereby incorporated by reference for all that it discloses.

### BACKGROUND

Device qualification for DSBGA (Die-Sized Ball Grid Array), WCSP (Wafer Chip Scale Package), QFN (Quad Flat No lead) and other semiconductor devices involves electrical and reliability testing of a predetermined number of prototype devices that have been produced at a particular facility. There are number of occasions during device qualification in which physical handling of a device occurs. For example, loading of a semiconductor device (sometimes referred to herein as a “DUT,” “device under test,” or simply “device”) into various test equipment, such as ATE (automatic test equipment) biased reliability test equipment, such as B-HAST (Biased Highly Accelerated Stress Test), Autoclave, etc., and removing the device from such equipment all require handling of the device. However, handling of a device may cause catastrophic damage, chipping or loss of the device (especially with small and extremely small die sizes). Handling may thus cause qualification failures that are not related to the quality of the device.

A number of reliability tests require stressing of a device under bias. The current technique for doing this involves mounting the device (typically by soldering) on a conversion printed circuit board (PCB). The device mounting process includes a number of cleaning and processing steps, which have inherent risk of damaging the device before the bias reliability test is even conducted. If the device fails any of the bias reliability tests, separate failure analysis testing of the device must be performed. In the event of bias reliability test failure, the device must be removed from the PCB and cleaned to remove solder flux before failure analysis on the device is conducted. These process steps required after reliability test failures, introduce further opportunities for handling-related device failures.

In addition to the risk of handling-related failures there are other problems inherent in current device qualification procedures. Variations in the printed circuit boards on which devices are mounted for testing introduce a separate set of variables. These variables include: the type of board material that is used; design variations between boards; the type of flux used to attach a device to a conversion board; and variations in the cleaning process used for flux removal.

### SUMMARY

Testing assembly embodiments described herein overcome device handling related problems of the prior art by providing a carrier assembly that holds a plurality of DUTs at predetermined positions in the carrier assembly. The carrier assembly in one embodiment is operably connectable to a plurality of different test socket assemblies, allowing multiple tests to be performed on the DUTs without between-test handling of the DUTs.

One testing assembly embodiment also includes a universal test socket adapted for testing groups of DUTs that have different external conductor configurations. In this embodiment the testing assembly is adapted for testing different groups of semiconductor devices, in which the semiconductor devices in each group have different external conductor configurations from those of the semiconductor devices of the other groups. This testing assembly also includes a number of different carrier assemblies. Each carrier assembly is adapted to hold semiconductor devices that all have the same external conductor configuration. (For example one carrier assembly may hold devices that each have a 3×3 bump array and another carrier assembly may hold devices that each have a 5×5 bump array and another may hold devices that each have a 10×10 bump array.)

The universal socket assembly associated with these multiple carrier assemblies has a series of identical conductor pin grids. Each pin grid is adapted to engage one semiconductor device in any carrier assembly that may be mounted on the universal socket assembly. Each different carrier assembly has a registration position with the universal socket assembly that aligns all of the devices in the carrier assembly with the appropriate pins in each pin array of the universal socket assembly. (For example the universal socket assembly may have a series of 10×10 pin arrays. Nine pins in each of the 10×10 pin arrays can be operably connected with each 3×3 bump device held in a first carrier assembly. Also, 25 pins of each 10×10 pin array may be operably connected to each 5×5 bump device held in a second carrier assembly, etc.)

The first and second carrier assemblies in the above example are each adapted to be attachable to the universal socket assembly in a registration/alignment position in which each device in the carrier assembly is properly aligned with the correct pin set of the associated 10×10 pin array. The universal socket assembly is also configured so that it is attachable to a test board with the pins in the socket assembly positioned in contact with predetermined conductor surfaces of the test board. Of course carrier assemblies and universal socket assemblies may be configured for any size pin array, i.e., neither the carrier assemblies nor the universal socket assembly is limited to a 10×10 pin array size.

### BRIEF DESCRIPTION OF THE DRAWINGS

FIG. 1 is a bottom isometric view of a prior art flip chip die.

FIG. 2 is an exploded isometric view of a multiple device under test (“DUT”) carrier assembly.

FIG. 3 is an isometric view of the carrier assembly of FIG. 2 in an assembled state.

FIG. 4 is an exploded isometric view of a socket assembly.

FIG. 5 is an isometric view of the socket assembly of FIG. 4 in an assembled state.

FIG. 6 is a side elevation view of a spring pin assembly.

FIG. 7 is a top plan view of the socket assembly a FIG. 5 mounted on a reliability test board.

FIG. 8 is a top isometric view of a plurality of socket assemblies mounted on a reliability test board.

FIG. 9 is a top isometric view of a carrier assembly mounted on a socket assembly that is, in turn, mounted on a reliability test board.

FIG. 10 is an isometric view of a carrier assembly mounted on a socket assembly.

FIG. 11 is an isometric view of an ATE socket in an open state.

FIG. 12 is an isometric view of the ATE socket of FIG. 11 in a closed state with a carrier assembly operatively mounted therein.

FIG. 13 is an exploded cross-sectional view of another embodiment of a carrier assembly.

FIG. 14 is a top plan view of a bottom portion of the carrier assembly of FIG. 13.

FIG. 15 is a top plan view of a top portion of the carrier assembly of FIG. 13.

FIG. 16 is a cross-sectional side elevation view of the assembled carrier assembly of FIG. 13 positions above a socket assembly.

FIG. 17 is a top plan view of the socket assembly of FIG. 16 mounted on a test printed circuit board.

FIG. 18 is a top plan view of a bottom plate of another embodiment of a carrier assembly.

FIG. 19 is an isometric bottom view of a top plate of the carrier assembly of FIG. 18.

FIG. 20 is an isometric top view of a universal socket assembly, showing a projected position of the device under test shown in FIG. 18.

FIG. 21 is a detail cross-sectional view of the carrier assembly of FIGS. 18 and 19, mounted on the socket assembly of FIG. 20.

### DETAILED DESCRIPTION

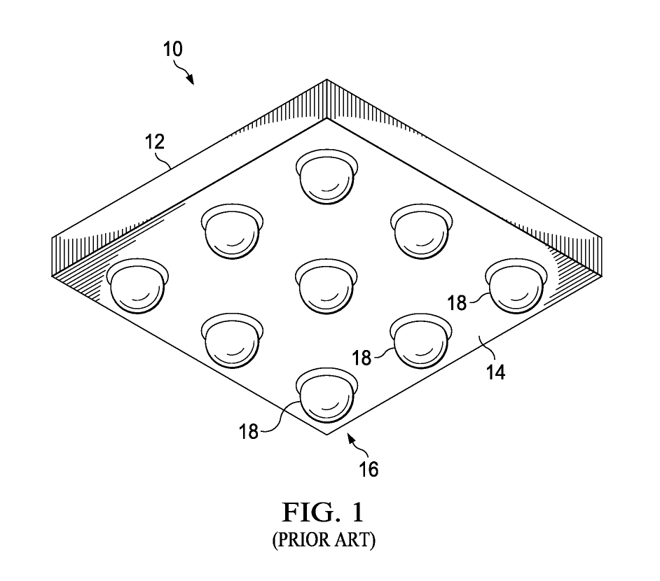

FIG. 1 is a bottom isometric view of a conventional flip chip die 10. The die 10 has a top face 12 and an active bottom face 14. The bottom face has a solder bump array 16 formed on it. The solder bump array 16 may comprises a 3×3 array with nine individual solder bumps 18. A The carrier assemblies and associated socket assemblies described herein are adapted to test multiple devices such as die 10 in an efficient, convenient, and cost-effective manner that eliminates many of the handling steps of conventional testing procedures.

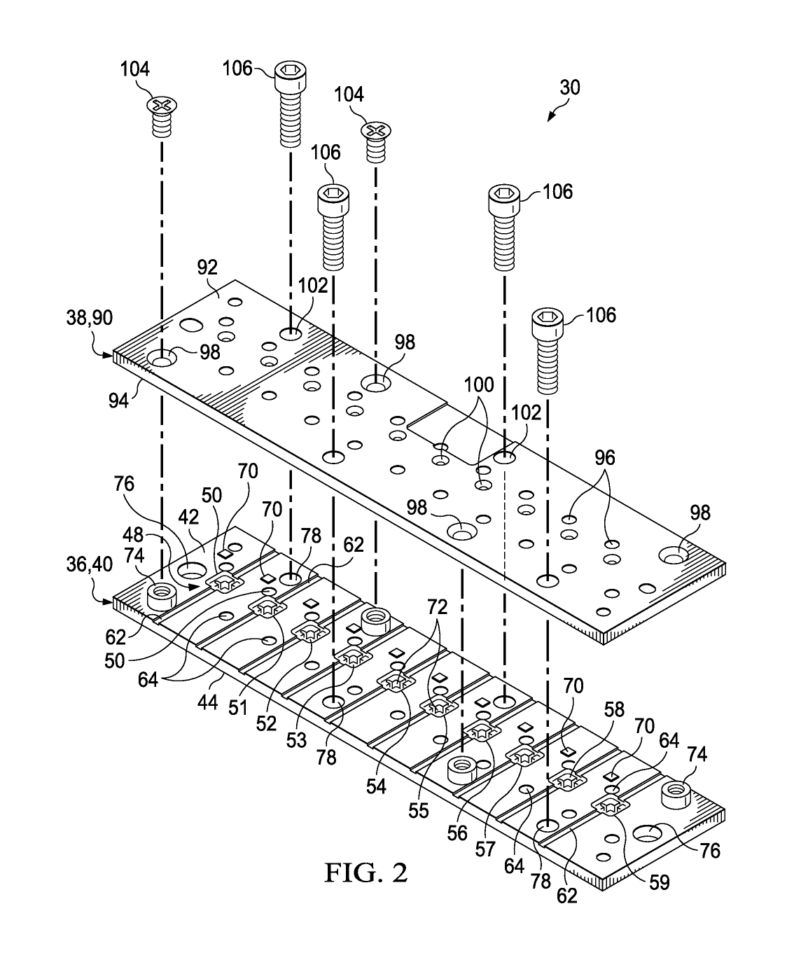

FIG. 2 is an exploded isometric view of a multiple device under test (“DUT”) carrier assembly 30, which may be referred to herein simply as “carrier assembly 30, or carrier 30.” The DUT's, which the carrier assembly 30 is adapted to carry may be conventional flip chip dies, such as die 10, or various other semiconductor devices. The carrier assembly 30 shown in FIG. 2 has a bottom portion 36, which may be a bottom plate 40. The carrier assembly 30 has a top portion 38, which may be a top plate 90. The bottom plate 40 has a top surface 42 and a bottom surface 44. A plurality of pockets 48 are formed on the top surface 42, and may comprise individual pockets 50-59. A laterally extending groove 62 may intersect each of the pockets 48. The grooves 62 are adapted to provide conditioning (temperature, pressure, and humidity) air to the pockets 48. Two ATE socket registration holes 64 are positioned adjacent on opposite sides of each of the pockets 48. The pockets 48 are each adapted to receive and operably support a DUT 70, such as die 10, which in FIG. 2 are shown positioned above associated pockets. A hole 72 is provided at the center of each of the pockets 48. The hole 72 is adapted to receive an end portion of a multiple pin spring pin assembly, as further described below. Four bosses 74 having threaded holes therein extend upwardly from the upper surface 42 of the plate 40 and are located adjacent to edge portions of the plate 40. A hole 76 for receiving a socket alignment pin (not shown) is provided at each end of the plate 40. Four holes 78 extend through the plate to facilitate attachment of the carrier assembly 30 to a socket assembly and test board, as described further below.

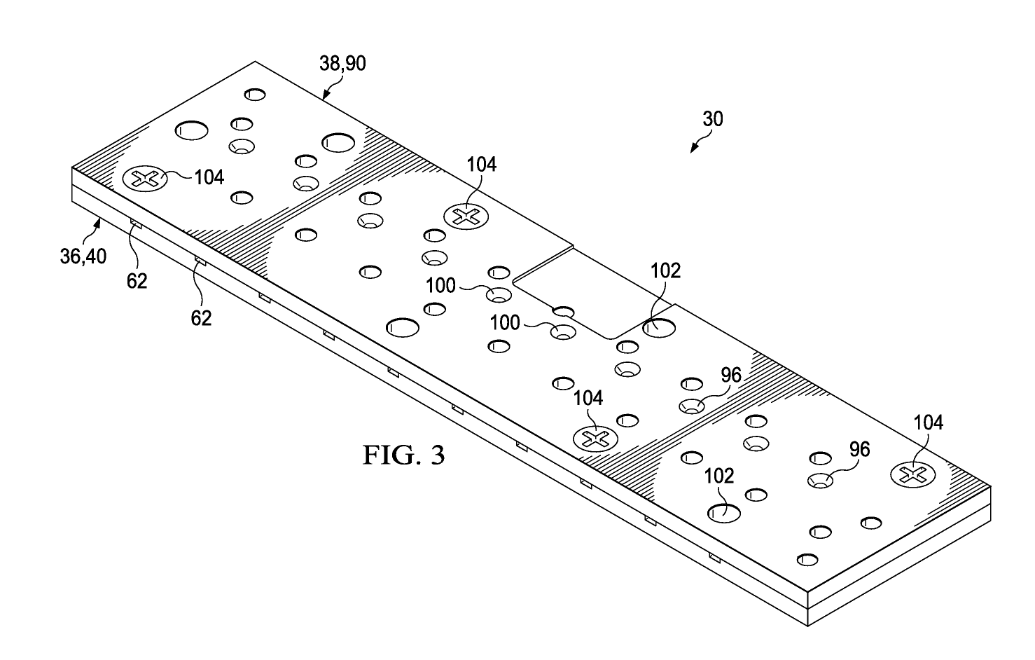

The top portion 38 of the carrier assembly 30 may comprise a top plate 90 having a top surface 92 and a bottom surface 94. A plurality of ATE registration holes 96 are adapted to be positioned above the ATE registration holes 62 in the bottom plate 30. A plurality of recessed holes 98 are adapted to be aligned with the bosses 74 on the lower plate 40. DUT conditioning holes100 are arranged to be positioned over corresponding pockets 48 in the lower plate 30. Four holes 102 in plate 90 are adapted to be aligned with holes 78 in the lower plate 30. A plurality of plate attachment screws 104 are received in the recessed holes 98 and associated bosses 74. Four holes 102, which are adapted be aligned with holes 78, receive socket attachment screws 106 therethrough to attach the carrier assembly 30 to a socket assembly, as described in further detail below. FIG. 3 shows the carrier assembly of FIG. 2 in an assembled state.

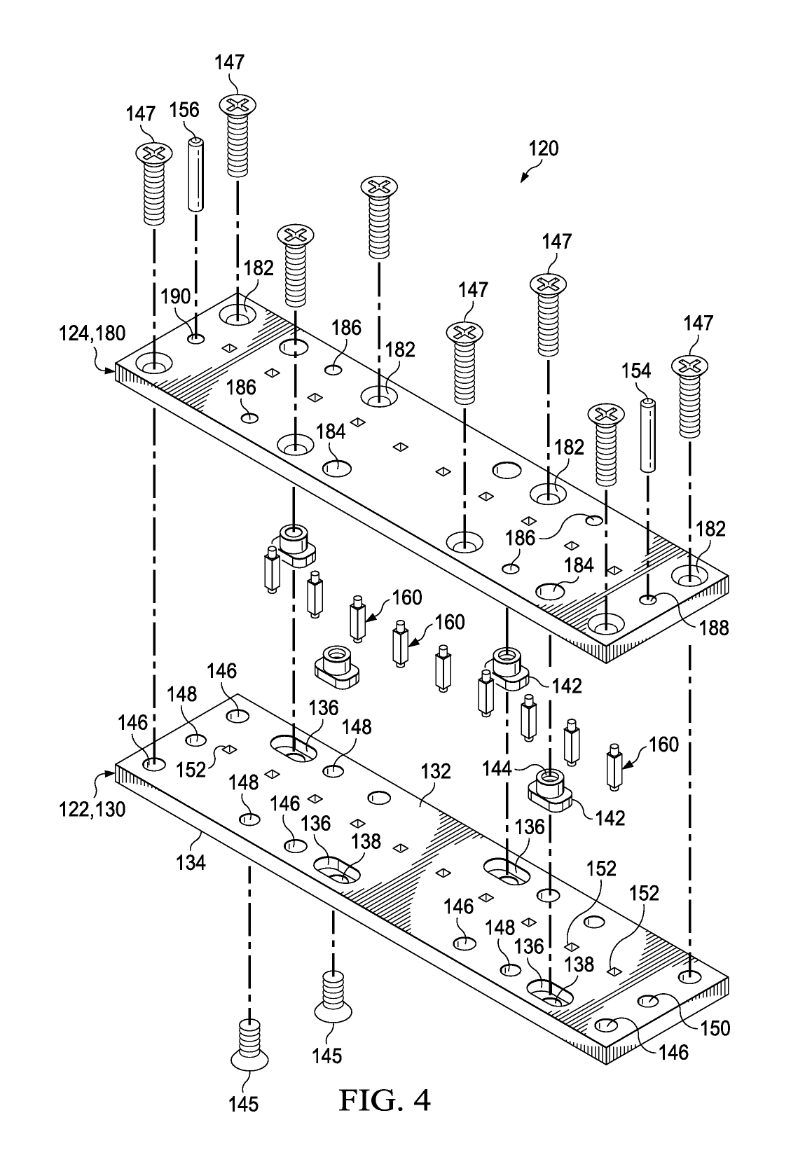

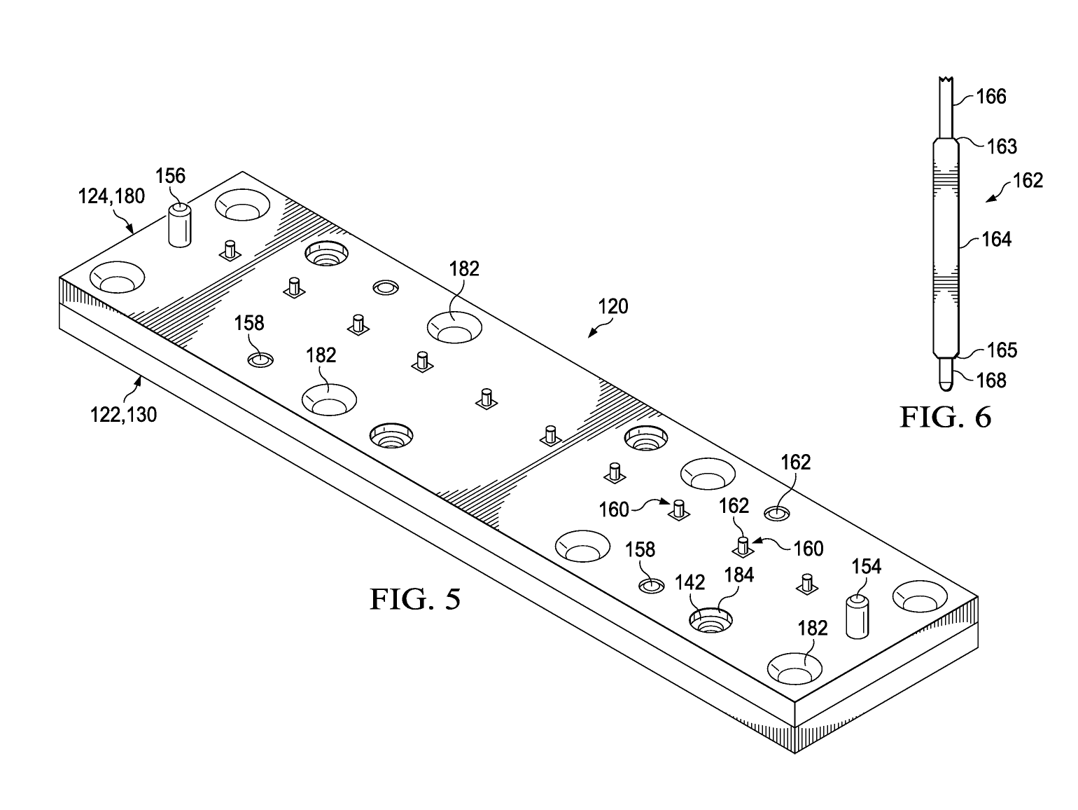

FIG. 4 is an exploded isometric view of a socket assembly 120 of a type that is adapted to be used with a carrier assembly, such as carrier assembly 30. FIG. 5 is an assembled isometric view of the socket assembly 120 of FIG. 4. The socket assembly 120 has a bottom portion 122 and a top portion 124. The bottom portion 122 may be provided by a bottom plate 130 having a top surface 132 and a bottom surface 134. The bottom plate 130 has a number of recessed slots 136 therein with a hole 138 at the base of each slot 136. Boss members 142 are received in the slots 136 with the hole 144 in the boss member aligned with the hole 138 in the slot. Boss member attachment screws 145 are used to attach the boss members 142 to the plate 130. Threaded holes 146 are adapted to receive screws 147 for attaching the top plate 180 to the bottom plate 130. Alignment pin holes 148 and 150 are adapted to receive alignment pins 154, 156. A plurality of seating pin holes 146 are adapted to receive seating pins 158 (shown in FIG. 5 only). A plurality of spring pin holes 152 extends through the bottom plate 130 and are adapted to be positioned in alignment with DUT's mounted in associated carrier assembly 30. The spring pin holes152 each receive a spring pin assembly 160 therein. In the embodiment of FIGS. 4 and 5, each spring pin assembly 160 has a 3×3 array of individual spring pins 162, FIG. 6. Because of the relatively small size of each individual spring pin 162, the multiple spring pins 162 of each spring pin assembly are not shown in detail in FIG. 4.

FIG. 6 is a side elevation view of an individual spring pin 162. Spring pin 162 has a barrel portion 164 having terminal ends 163 and 165. A top plunger member 166 is received in the barrel portion 164 and extends upwardly from the top end 163 of the barrel portion. The bottom plunger member 168 extends downwardly from the bottom end 165 of the barrel portion 164. Each of the plunger members 166, 168 is attached to an internal spring assembly (not shown). Spring pins as described herein are known in the art and are sometimes referred to as “pogo pins.” FIG. 6 illustrates the fully extended position of each of the plunger members 166, 168. Inwardly directed pressure on the ends of a plunger members 166 or 168 causes the plunger members to move into retracted positions. In one embodiment, in the retracted position of each of the plunger members 166, 168 the terminal end portion thereof is flush with an associated terminal end 163, 165 of the barrel portion 164.

Returning again to FIGS. 4 and 5, the top plate 180 as eight countersunk holes 182 therein, which are aligned with holes 146 in the bottom plate 130. The countersunk holes 182 receive screws 147 therethrough to attach the top plate 180 to the bottom plate 130. Holes 184 are adapted to be aligned with the boss members 142 mounted on the lower plate. Elongate screws 106, FIG. 2, pass through holes 78, 102 in the carrier assembly 30 and holes 184 in the socket assembly top plate 180 and are thread into the boss members 142. The elongate screws 106 attach the carrier assembly 30 to the socket assembly 120 The top plate 180 also comprises seating pin holes 186 and alignment pin holes 188, 190. The seating pin holes 188 receive small seating pins 158 therein (shown only in FIG. 5) that facilitate alignment and seating of the carrier assembly 30 with the socket assembly 120. Alignment pins 154 and 156 are received in the alignment pin holes 188 and 190, respectively. The alignment pins 154, 156 facilitate alignment of the carrier assembly 30 with the socket assembly 120.

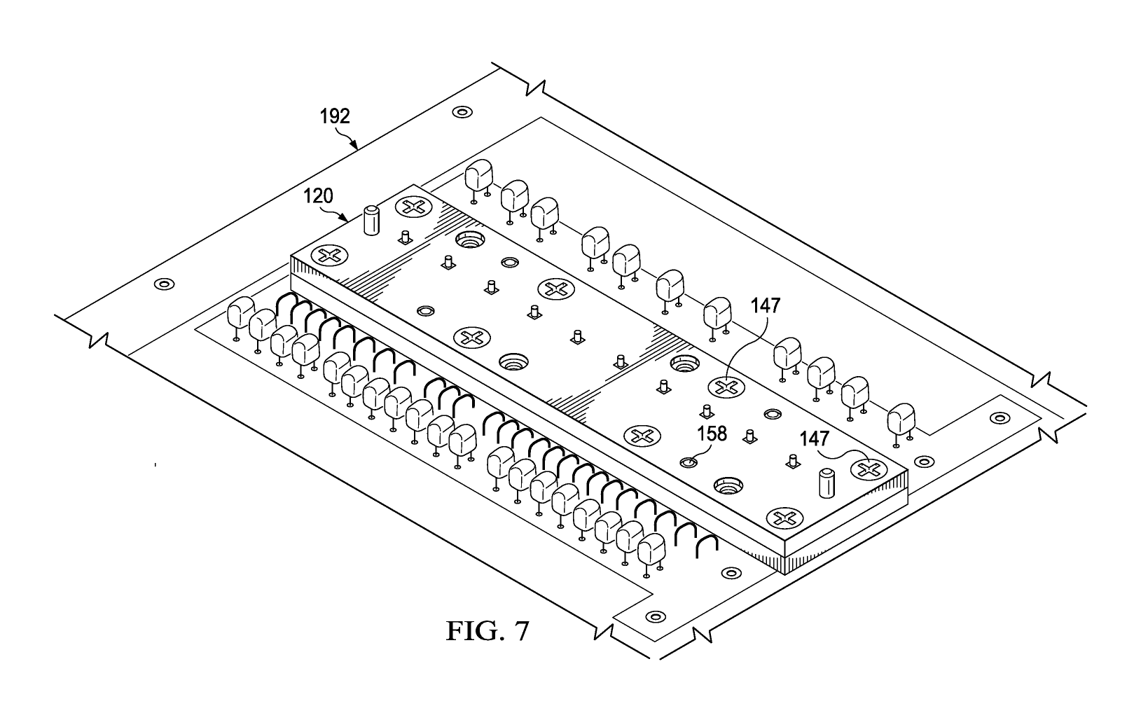

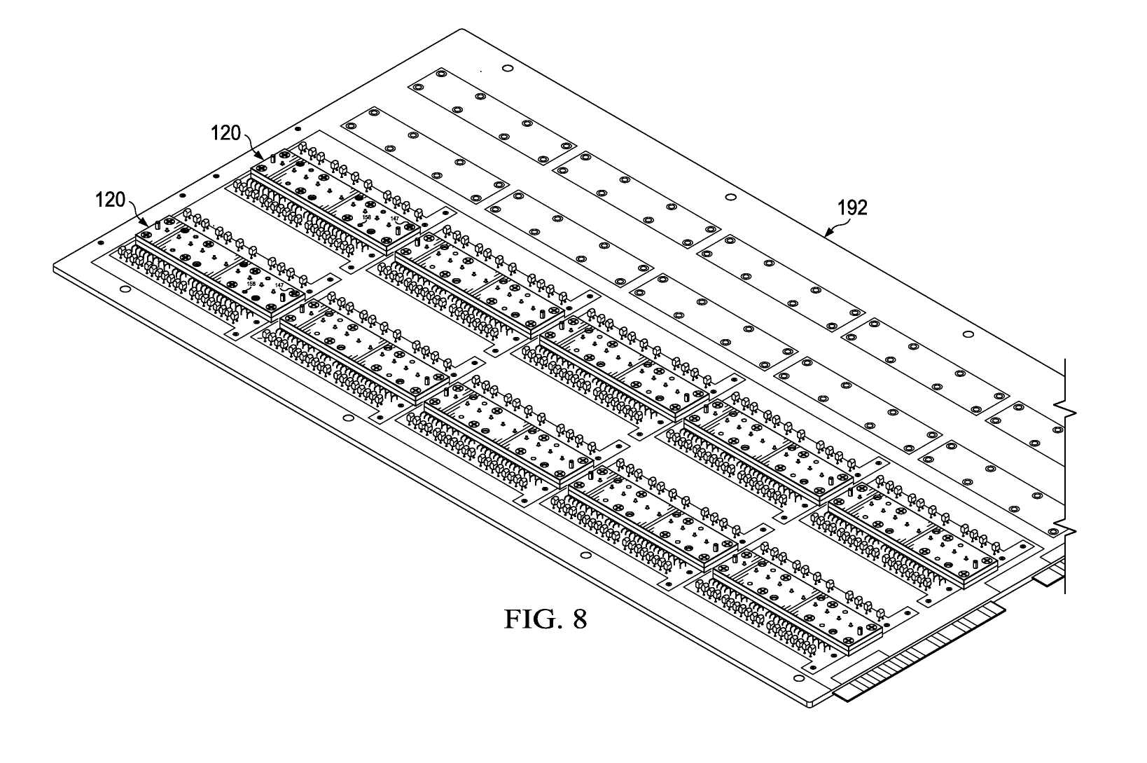

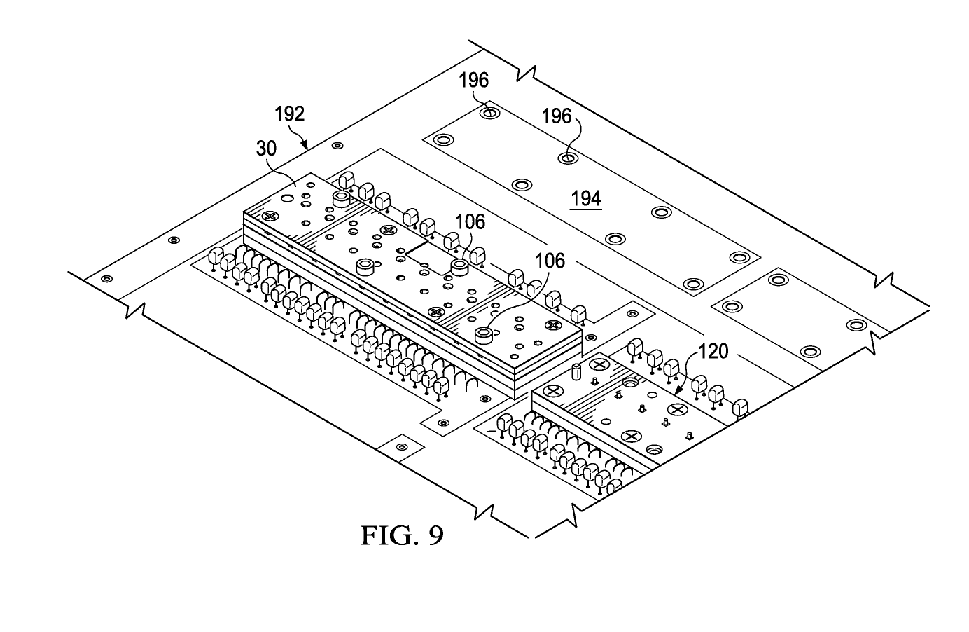

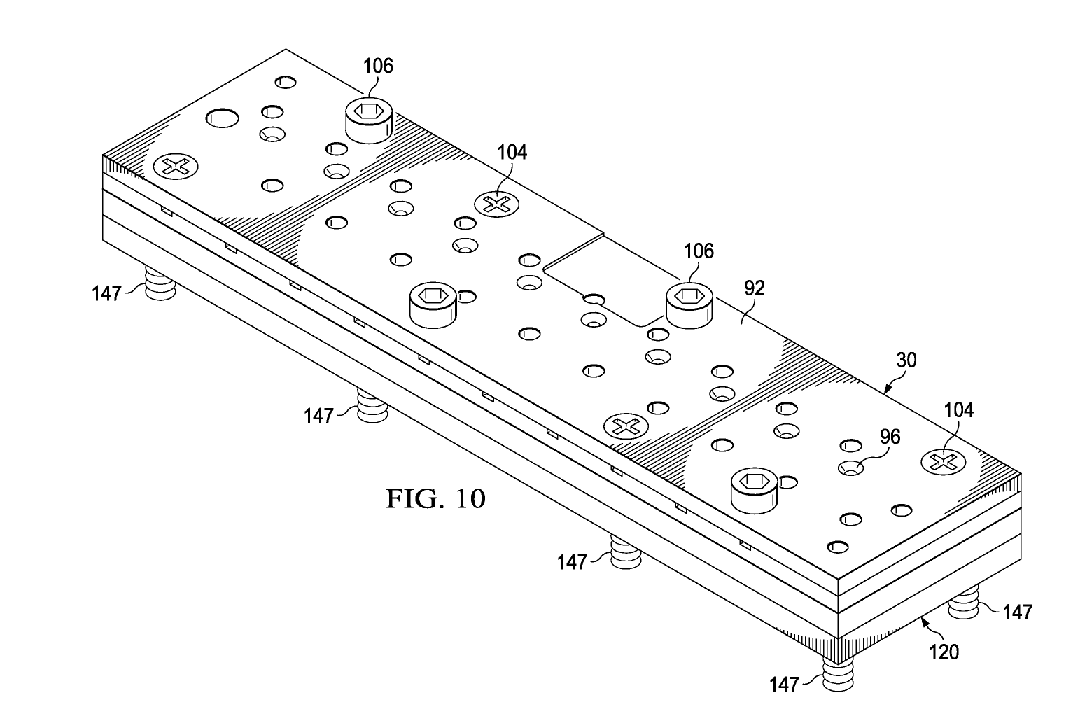

FIGS. 7, 8 and 9 illustrate a reliability test board 192, which in the illustrated embodiment is a bHAST board. The reliability test board 192 has a test socket attachment area 194, FIG. 9. The test socket attachment area 194 has eight holes 196 therein. FIG. 10 illustrates a carrier assembly 30 attached to a test socket 120. Eight attachment pins 147 (only four shown in FIG. 10) extend from the bottom of the test socket 120 and are received in the holes 196 in the board 192 to attach test socket 120 to the reliability test board 192.

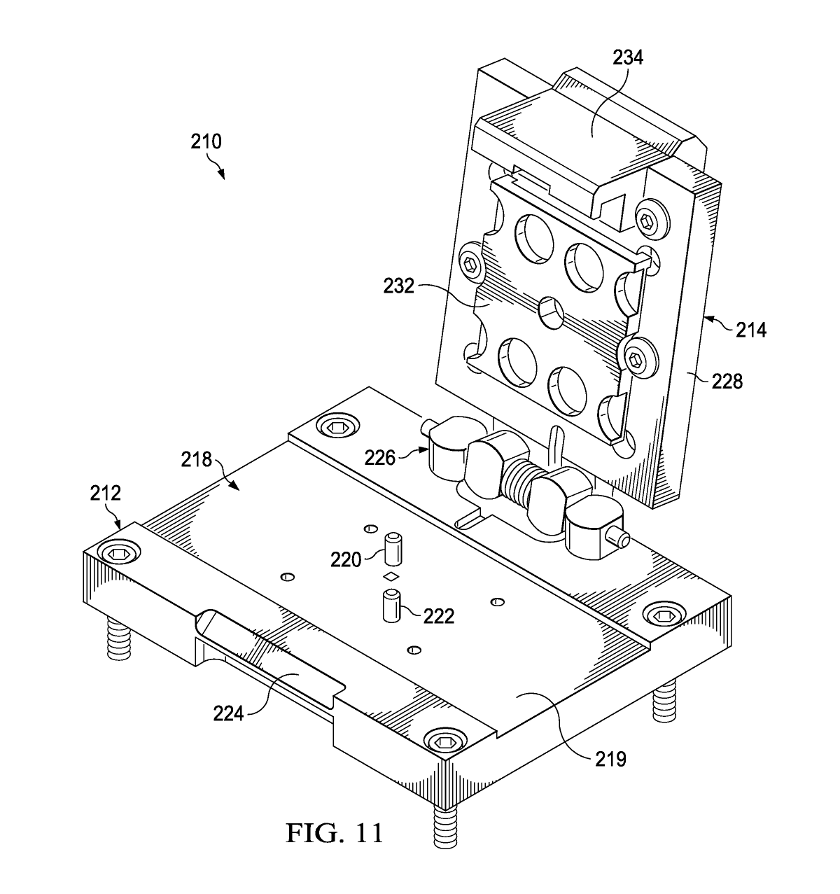

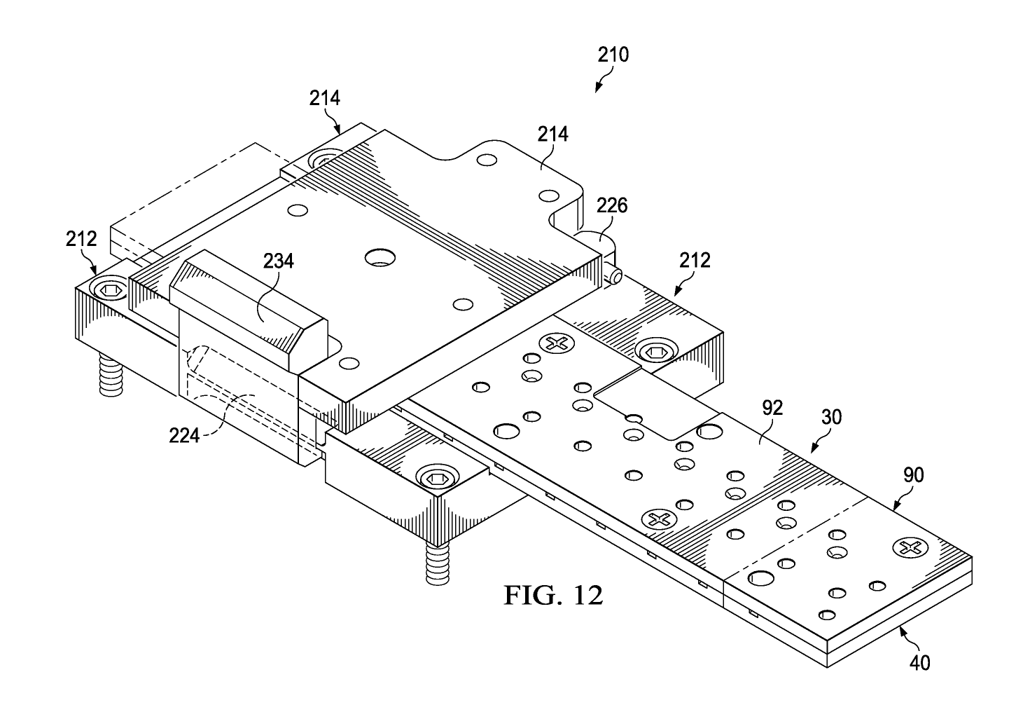

FIGS. 11 and 12 illustrate an ATE socket assembly 210 adapted to receive and test DUTs in the carrier assembly 30. The ATE socket assembly 210 has a stationary portion 212 and a pivotally displaceable portion 214. The stationary portion 212 has an elongate recess 218 in an upper portion thereof. The elongate recess 218 comprises a flat surface 219 having upwardly projecting indexing pins 220, 222 extending therefrom. These indexing pins 220, 222 are received in indexing holes 62, FIG. 2, in the lower plate 40 of the carrier assembly 30.

As best illustrated in FIG. 11, the stationary portion 212 has a catch 224 formed thereon. A pivot assembly 226 pivotally attaches the stationary portion 212 to the displaceable portion 214. The pivotally displaceable portion 214 has a main body 228 that has a compressible resilient plate 232 mounted thereon. The compressible plate 232 is adapted to engage an upper surface 92 of the carrier assembly 30 to hold it in stationary relationship with the ATE socket assembly 210. A deflectable latch member 234 mounted on the displaceable portion 214 is adapted to cooperate with the catch portion 224 formed on the stationary portion 212.

in operation, the pivotally displaceable portion 214 of the socket assembly 210 is moved to an open position and a carrier assembly 30 is mounted at a predetermined longitudinal position on the stationary portion 212 by placing indexing pins 220, 222 in selected indexing holes in the carrier assembly 30. These indexing pins 220, 222 may hold the carrier assembly 30 at 10 different registration positions with respect to the ATE socket assembly of the illustrated embodiment. Testing of a different DUT 70 is performed at each of these 10 different registration positions. One of the test positions is shown in solid lines in FIG. 12 and another test position is shown in phantom lines. Testing in the ATE socket assembly 210 is performed by a test program, which collects data for each device verifying its functionality and parametric performance.

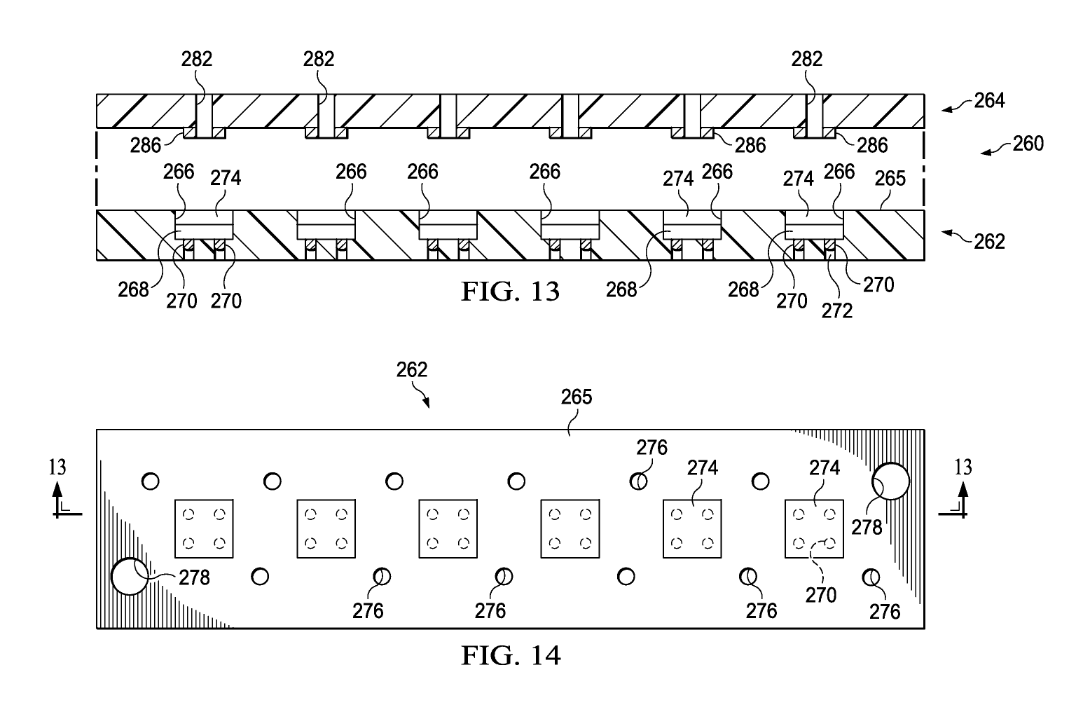

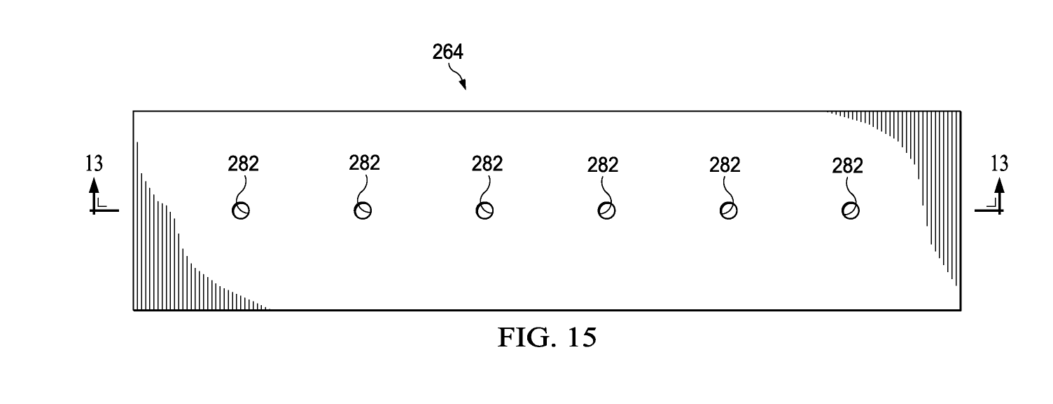

FIG. 13 is an exploded cross-sectional elevation view of another embodiment of a carrier assembly 260. The carrier assembly 260 has a bottom plate 262 and a top plate 264. FIG. 14 is a top view of the bottom plate 262. FIG. 15 is a top view of the carrier assembly top plate 264. The bottom plate 262 has a top portion 265 having a number of pockets 266 formed therein. The pockets 266 are adapted to receive DUTs 268, each having four solder bumps 270. In this embodiment, the bottom plate 262 is adapted to receive six DUTs 268. A compressible pad 274 is positioned above each DUT 268. A spring pin receiving opening 272 is positioned beneath each solder bump 270 of each DUT, as best shown in FIG. 13. As best shown in FIG. 14, indexing (registration) holes 276, are provided in the bottom plate 262 on either side of the pockets 266 for indexing the carrier assembly 262 to an ATE socket. Air holes 282 are provided in the top plate 264 in alignment with each of the pockets 266 in the bottom plate 262. The top plate 264 has a fixed plunger structure 286 formed on a bottom surface thereof. The plunder structure 286 is positioned above each of the pockets 266. Plunger structure 286 is adapted to compressibly engage an associated compressible pad 274 that is positioned above each DUT 274, when the top plate 264 is attached to the bottom plate 262.

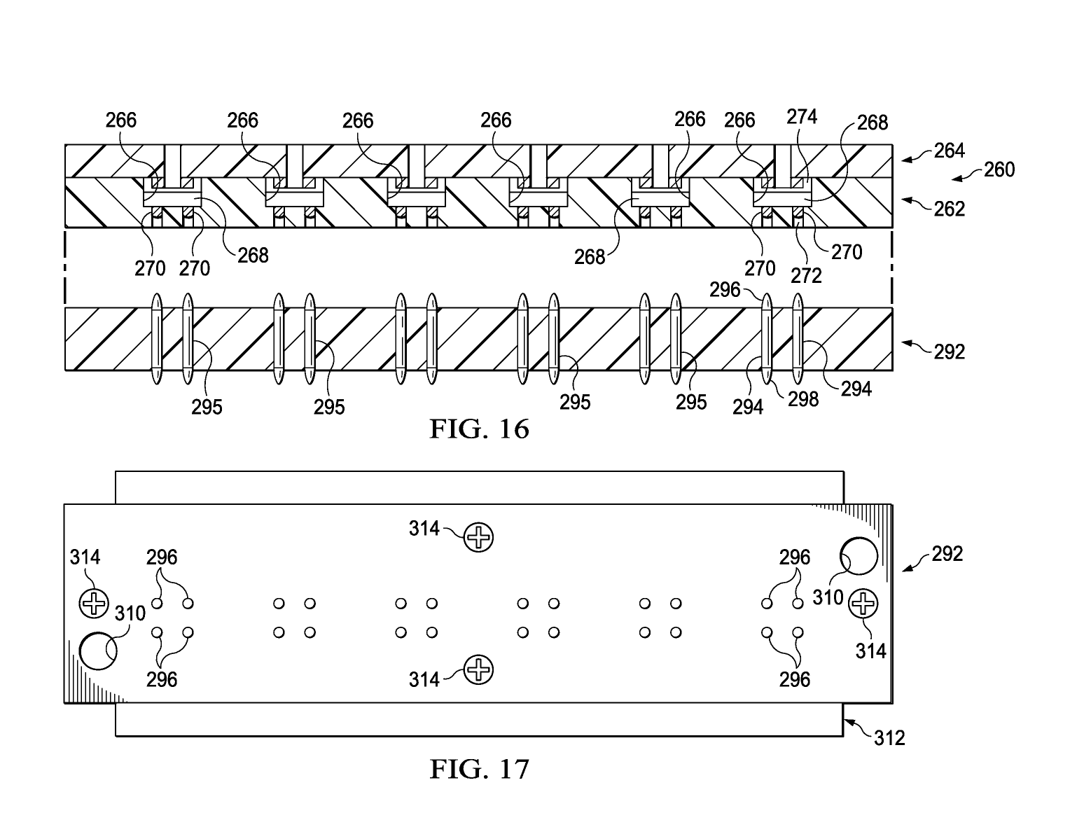

FIG. 16 is a cross-sectional side elevation view of the assembled carrier assembly 262 of FIGS. 13-15 mounted above a socket assembly 292. A plurality of spring pins 294 are mounted in spring pin holes 295 of the socket assembly 292. A top plunger portion 296 of each spring pin 294 is aligned with and adapted to engage a solder bump 270 positioned above it. A bottom plunger portion 297 of each spring pin is adapted to engage an associated portion of a test circuit board 312, FIG. 17, positioned below it.

FIG. 17 is a top plan view of the socket assembly 292 of FIG. 16 mounted on a test circuit board 312. Registration holes 310 for registering the socket assembly with the carrier assembly 264 may be provided at two corner portions of the socket assembly 292, as shown in FIG. 17. FIG. 17 also illustrates the positions of plunger portions 296 of spring pins 294, shown in FIG. 16.

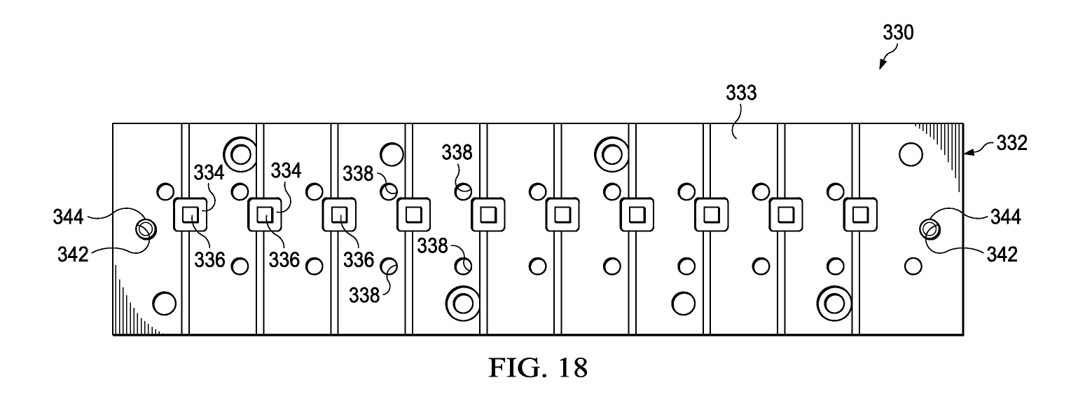

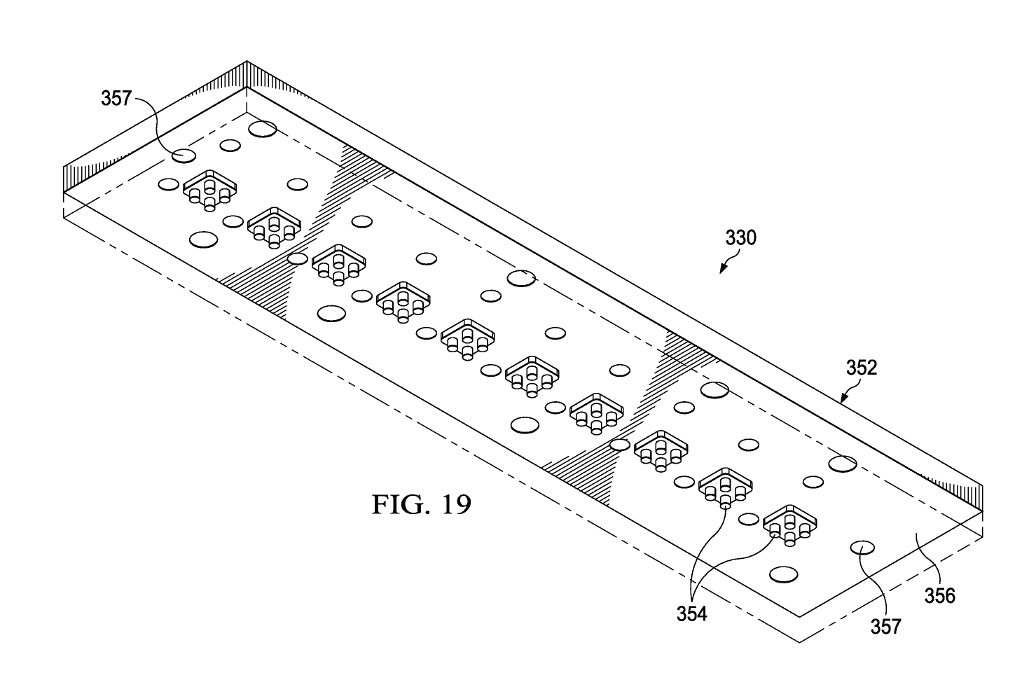

FIG. 18 is a top plan view of a bottom plate 332 of another carrier assembly 330. The bottom plate 332 has 10 DUT pockets 334 formed in an upper surface 333 thereof. A DUT is mounted in each of the pockets 336. Indexing holes 338 for an ATE socket 338 are provided on either side of each pocket 334. A conditioning air vent channel 340 intersects each pocket 334. Holes 342 are positioned at either end of the bottom plate 332 for receiving alignment pins 344. FIG. 19 is a bottom isometric view of a top plate 352 of the carrier assembly 330. Plunger structures 354 extends downwardly from a bottom surface 356 of the top plate 352 at positions adapted to be aligned with pockets 334 of the bottom plate 332. Alignment pin holes 357 are provided at either end of the upper plate 352.

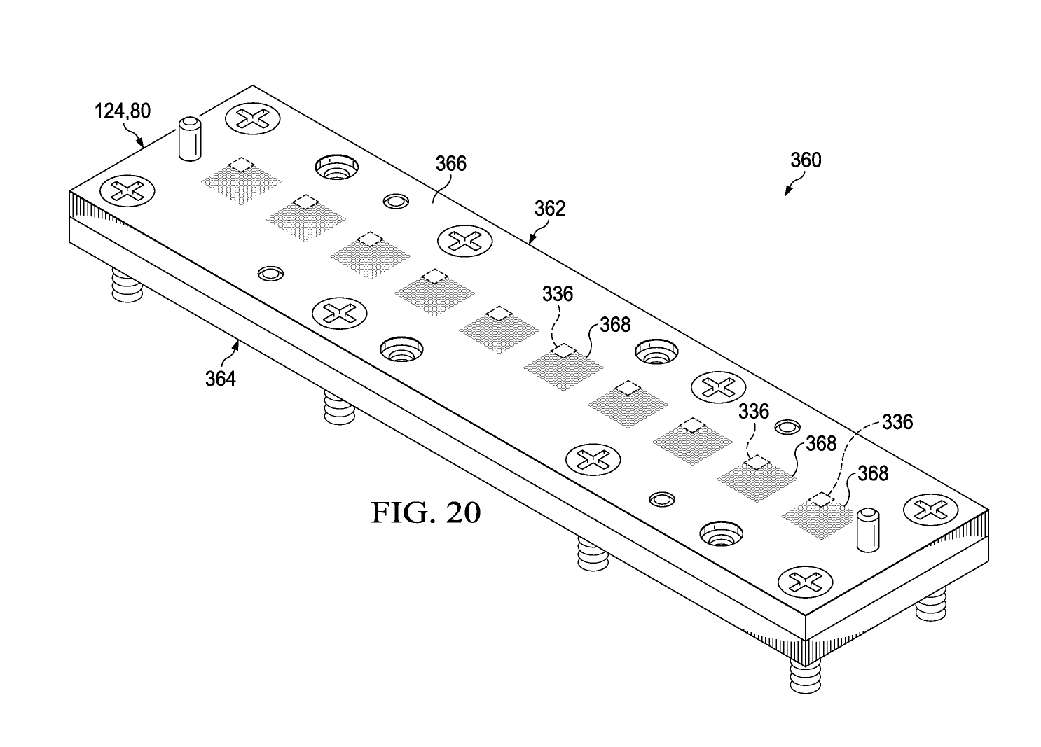

FIG. 20 is a top isometric view of a universal base socket assembly 360. The universal socket assembly includes a top plate 362 and a bottom plate 364. A top surface 366 of the top plate 362 has a plurality of spring pin arrays 368 arranged in linear alignment thereon. Each spring pin array 368 in the embodiment of FIG. 20 is a 10×10 spring pin array. The projected position of DUTs 336 mounted in an associate carrier assembly 330, shown in FIG. 18, are indicated in FIG. 20 by dashed line squares. The device under test 360 in FIG. 18 is a four bump flip chip. Its projection in FIG. 20 covers four pins in of the 100 pin array. Each spring pin array 368 is adapted to operably receive a DUT of any number of solder bumps from 1 bump to 100 bumps. Each carrier assembly used in association with the universal socket assembly 360 must have the pockets thereof appropriately positioned so that the DUTs contained therein will be positioned above the appropriate pins of the associated spring pin array 368.

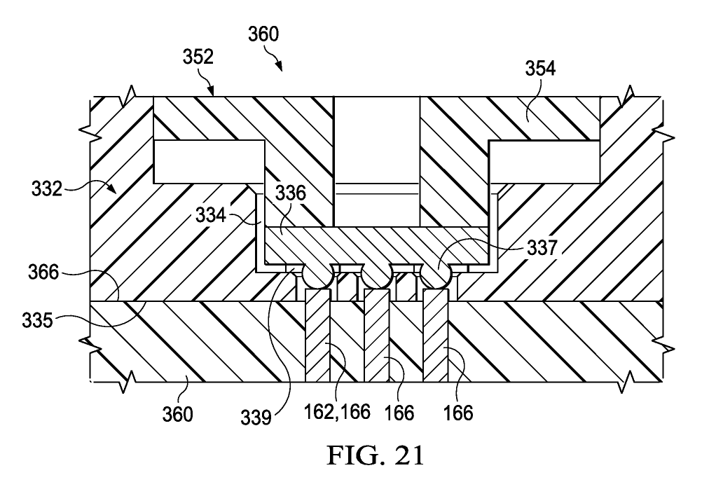

FIG. 21 is a detail cross-sectional view of a DUT pocket 334 region of the carrier assembly 330, shown in FIGS. 18 and 19. The carrier assembly 330 is mounted on the universal socket assembly 360, shown in FIG. 20. The bottom plate 332 and top plate 352 of the carrier assembly 330 are engaged. A DUT 336 is mounted in the pocket 334. The DUT 336 has a plurality of solder bumps 337 extending downwardly from the DUT 336. In one embodiment the DUT 336 is supported on a nonconductive via-hole array 339 at the bottom of the pocket 334 through which the solder bumps 337 project. A top surface 366 of the socket assembly 364 is nonconductive in the region where plunger members 166 extend through it. This top surface 366 of the socket assembly engages the bottom surface 335 of the carrier assembly bottom plate 332.

Plunger structure 354 of the carrier top plate 352 extends into the pocket 334 and engages an upper surface of the DUT 336 urging the DUT against the via hole array 339. A spring pin 162 upper plunger member 166 is engaged with each of the DUT bumps 337 and is urged downwardly thereby into the compressed position shown in FIG. 21. Each spring pin 162 is also engaged with circuitry on a test board (not shown in FIG. 21) on which the socket assembly 360 is mounted. Thus, test signals are sent from the test board to the DUT's 336 through the spring pins 162.

Some semiconductor testing assembly embodiments described herein may provide some or all of the following advantages over conventional semiconductor testing assemblies: shortened reliability test cycle times; complete elimination or minimization of semiconductor device handling during preconditioning; elimination of certain variables associated with board mounting and cleaning of semiconductor devices during testing; elimination of certain expenses associated with board mounting and cleaning of semiconductor devices during testing; elimination of the use and cost of carrier trays; enablement of batch process testing of semiconductor devices; reduction or elimination of invalid failures; simplification of the failure analysis process by elimination of die demounting and re-balling processes; and decreased parasitic inductance provided by decreasing the distance between active components on a biased reliability test board and semiconductor device contacts.

Although certain embodiments of semiconductor device test assemblies, including carrier assemblies and socket assemblies, have been expressly described in detail herein, alternative embodiments of these test assemblies will occur to those skilled in the art after reading this disclosure. It is intended that the language of the appended claims be broadly construed to cover such alternative embodiments, except to the extent limited by the prior art.

What is claimed is:

1. A testing assembly for testing a plurality of semiconductor devices comprising:
a carrier assembly adapted to hold said plurality of semiconductor devices at predetermined locations therein for testing thereof; and
a socket assembly operably engageable with said carrier assembly in at least one registration position.

2. The testing assembly of claim 1, further comprising a test circuit on which said socket assembly is removably operably mountable in at least one predetermined registration position.

3. The testing assembly of claim 2 further comprising a plurality of conductor members received in said socket assembly and adapted to transmit electrical signals between said test circuit and said plurality of semiconductor devices.

4. The testing assembly of claim 3 wherein said plurality of conductor members comprise spring pins.

5. The testing assembly of claim 1 wherein said carrier assembly comprises a plurality of pockets adapted to receive said semiconductor devices in a predetermined orientation therein.

6. The testing assembly of claim 5 wherein each carrier assembly comprises an upper portion and a lower portion and wherein said plurality of pockets are located in said lower portion.

7. The testing assembly of claim 6 wherein said upper portion of said carrier assembly comprises plunger structure adapted to be aligned with said pockets in said bottom portion for stably holding said plurality of semiconductor devices in said pockets.

8. The testing assembly of claim 6 wherein said upper portion comprises conditioning air holes positioned above said pockets in said lower portion.

9. The testing assembly of claim 6 wherein said lower portion comprises laterally extending grooves intersecting each of said pockets for providing conditioning air thereto.

10. The testing assembly of claim 2 wherein said test circuit comprises a circuit board with a socket assembly receiving area thereon.

11. The testing assembly of claim 10 wherein said socket assembly receiving area comprises registration structure and wherein said socket assembly comprises registration structure for co-acting with said receiving area registration structure for holding said socket assembly in a predetermined registration position with said socket assembly receiving area.

12. The testing assembly of claim 2 wherein said carrier assembly, said socket assembly and said test circuit are adapted to co-act to simultaneously test said plurality of semiconductor devices held in said carrier assembly.

13. The testing assembly of claim 1 wherein said socket assembly operably engageable with said carrier assembly in at least one registration position is operably engageable with said carrier assembly in a plurality of registration positions.

14. The testing assembly of claim 13 wherein said socket assembly is adapted to test a different one of said plurality of semiconductor devices in said carrier assembly at each of said plurality of registration positions.

15. The testing assembly of claim 1 wherein said socket assembly is an ATE test socket assembly.

16. The testing assembly of claim 2 wherein said socket assembly is a biased reliability socket assembly.

17. A testing assembly for testing a plurality of semiconductor devices comprising a carrier assembly adapted to hold said plurality of semiconductor devices at predetermined locations therein, said carrier assembly being operably connectable with a plurality of different socket assemblies for testing said plurality of semiconductor devices held by said carrier assembly.

18. A testing assembly for testing different groups of semiconductor devices, the semiconductor devices in each group having different external conductor configurations from those of the semiconductor devices of the other groups comprising:
a plurality of different carrier assemblies, each adapted to hold at predetermined locations therein semiconductor devices from a selected one of said different groups of semiconductor devices; and
a universal socket assembly comprising a plurality of identical conductor pin grids that are each operably engageable with semiconductor devices in said plurality of carrier assemblies in registration positions associated with each carrier assembly.

19. The testing assembly of claim 18 wherein said universal socket assembly comprises a plurality of spring pin grids.

20. The testing assembly of claim 18 wherein said semiconductor devices to be tested comprise external conductor arrays that are operably engageable with said pin grids.
